(19) United States
(12) Patent Application Publication
(10) Pub. No.: US 2011/0298750 A1
(43) Pub. Date: Dec. 8, 2011

(54) TOUCH-SENSITIVE DEVICE AND FABRICATION METHOD THEREOF AND TOUCH-SENSITIVE DISPLAY DEVICE

(76) Inventors: Wen-Chun WANG, Taichung City (TW); Ming-Kung Wu, Tai Chung County (TW); Chia-Chi Chen, Tai Chung County (TW); Chih-Jung Teng, Tai Chung-City (TW); Chin-Chang Liu, Taichung County (TW); Fa-Chen Wu, Yun Lin County (TW)

(21) Appl. No.: 13/151,868

(22) Filed: Jun. 2, 2011

(30) Foreign Application Priority Data
Jun. 4, 2010 (TW) 099118140

(51) Int. Cl. G06F 3/045; H05K 3/10

(52) U.S. Cl. 345/174; 427/97.3

(57) ABSTRACT

A touch-sensitive device includes a transparent substrate, a touch-sensing structure, a metal trace layer, a transparent conductive layer and a first insulation layer. The touch-sensing structure is disposed on the transparent substrate and located in a touch-sensitive region of the touch-sensitive device. The metal trace layer is disposed on a non-touch-sensitive region of the touch-sensitive device. The transparent conductive layer is connected to the metal trace layer. The first insulation layer covers at least the touch-sensing structure, the metal trace layer and the transparent conductive layer. At least one opening is formed on the first insulation layer to expose a part of the transparent conductive layer.

### BACKGROUND OF THE INVENTION

a. Field of the Invention

The invention relates to a touch-sensitive device, a fabrication method of the touch-sensitive device, and a touch-sensitive display device having the touch-sensitive device.

b. Description of the Related Art

Referring to FIG. 1, a conventional touch panel 100 has a glass substrate 102, a silicide layer 104 formed on the glass substrate 102, a plurality of touch-sensing electrodes (such as X-axis electrodes 106a and Y-axis electrodes 106b), a metal trace layer 108, a dielectric layer 110 and a decorative layer 112. The X-axis electrodes 106a and the Y-axis electrodes 106b may be arranged in two directions perpendicular to each other. The X-axis electrodes 106a and the Y-axis electrodes 106b are insulated from each other by an organic dielectric layer 110, and, as shown in FIG. 1, two adjacent Y-axis electrodes 106b are connected with each other by a conductive pad 114. The metal trace layer 108 includes a plurality of metal traces, and the silicide layer 116 covers the X-axis electrodes 106a, the Y-axis electrodes 106b and the metal trace layer 108 entirely to function as a passivation layer.

In order to electrically connect metal traces in the metal trace layer 108 with an external flexible printed circuit board (FPC)118, at least one opening is formed on the silicide layer 116 to exposed a part of the metal trace layer 108, and an anisotropic conductive film (ACF)120 is used to electrically connect the metal traces in the metal trace layer 108 with the flexible printed circuit board 118. However, such configuration, when undergoing subsequent fabrication processes, is liable to absorb surrounding moisture to cause severe erosion of metal traces and hence deteriorate the transmission efficiency of the metal traces.

### BRIEF SUMMARY OF THE INVENTION

The invention provides a touch-sensitive device, a fabrication method of the touch-sensitive device, and a touch-sensitive display device having the touch-sensitive device.

In order to achieve one or a portion of or all of the objects or other objects, one embodiment of the invention provides a touch-sensitive device having a touch-sensitive region and a non-touch-sensitive region and including a transparent substrate, a touch-sensing structure, a metal trace layer, a transparent conductive layer and a first insulation layer. The touch-sensing structure is disposed on the transparent substrate and located in the touch-sensitive region. The touch-sensing structure includes a plurality of first sensing series and a plurality of second sensing series. The metal trace layer is disposed on the non-touch-sensitive region. The transparent conductive layer is disposed on the transparent substrate, located in the non-touch-sensitive region, and electrically connected to the metal trace layer. The first insulation layer is disposed on the transparent substrate and covers the touch-sensing structure, the metal trace layer and the transparent conductive layer. At least one opening is formed on the first insulation layer to expose a part of the transparent conductive layer.

In one embodiment, a first buffer layer is formed on the transparent substrate to cover the transparent substrate and a decorative layer is disposed on the non-touch region, wherein the decorative layer is formed on the first buffer layer and the metal trace layer and the transparent conductive layer are formed on the decorative layer.

In one embodiment, a second insulation layer is disposed on the transparent substrate and distributed only in the non-touch-sensitive region. The thickness of the second insulation layer is preferably 10-50 times greater than the thickness of the first insulation layer. At least one opening is formed on the second insulation layer to expose the part of the transparent conductive layer, and the opening formed on the second insulation layer substantially overlaps the opening formed on the first insulation layer. Besides, the second insulation layer surrounds one side of the decorative layer.

In one embodiment, each of the first sensing series includes a plurality of first transparent electrodes connected with each other by a plurality first connecting lines, each of the second sensing series includes a plurality of second transparent electrodes connected with each other by a plurality of second connecting lines, the second connecting lines are formed in a fabrication process different to the fabrication processes of the first connecting lines, the first transparent electrodes and the second transparent electrodes, and a dielectric layer is disposed between the corresponding first connecting line and second connecting line.

In one embodiment, the material of the decorative layer includes at least one of diamond-like carbon, ceramic, colored ink, resin and photo resist.

In one embodiment, the transparent substrate is a glass substrate or a plastic substrate, the first insulation layer may be made from an inorganic material, the second insulation layer may be made from an inorganic material or an organic material, and the first buffer layer and the second buffer layer may be made from an inorganic material.

According to another embodiment of the invention, a touch-sensitive display device includes a touch-sensitive device and a display device in combination with touch-sensitive display device through, for example, an optical adhesive.

According to another embodiment of the invention, a fabrication method of a touch-sensitive device including the steps of providing a transparent substrate; forming a decorative layer on the transparent substrate; forming a metal trace layer on the decorative layer; forming a transparent conductive layer on the transparent substrate, wherein the transparent conductive layer is patterned to form a plurality of first sensing series and a plurality of second sensing series in a touch-sensitive region of the touch-sensitive device and to form a transparent conductive layer in a non-touch-sensitive region of the touch-sensitive device; forming an insulation layer on the transparent conductive layer, and forming at least one opening on the insulation layer to expose a part of the transparent conductive layer to enable the transparent conductive layer to electrically connect with an external circuit.

According to the above embodiments, the metal trace layer are surrounded by the first insulation layer and the transparent conductive layer to prevent the metal traces in the metal trace layer from absorbing moisture or suffering scrapes to improve production yields and reliability. Besides, the transparent conductive layer, the first transparent electrodes, the second transparent electrodes and the first connecting lines are formed in the same fabrication process to prevent additional fabrication processes and costs.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a cross-sectional schematic diagram of a conventional touch panel.

FIG. 2A shows a plan view of a touch-sensitive device according to an embodiment of the invention, and FIG. 2B shows an enlarged cross-section of FIG. 2A.

FIG. 3 shows a flow diagram illustrating a fabrication method of the non-touch-sensitive region N in the touch-sensitive device shown in FIG. 2.

FIG. 4 shows a cross-sectional schematic diagram of a touch-sensitive device according to another embodiment of the invention.

FIG. 5 shows a cross-sectional schematic diagram of a touch-sensitive device according to another embodiment of the invention.

FIG. 6 shows a cross-sectional schematic diagram of a touch-sensitive device according to another embodiment of the invention.

FIG. 7 shows a cross-sectional schematic diagram of a touch-sensitive device according to another embodiment of the invention.

FIG. 8 shows a cross-sectional schematic diagram of a touch-sensitive device according to another embodiment of the invention.

FIG. 9 shows a cross-sectional schematic diagram of a touch-sensitive device according to another embodiment of the invention.

FIG. 10 shows a cross-sectional schematic diagram of a touch-sensitive device according to another embodiment of the invention.

FIG. 11 shows a cross-sectional schematic diagram of a touch-sensitive display device according to an embodiment of the invention.

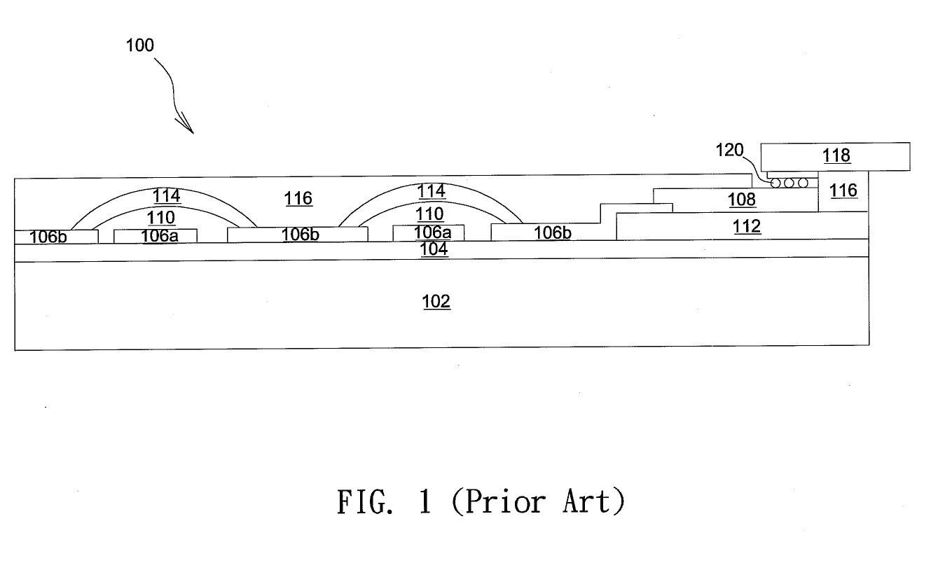

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

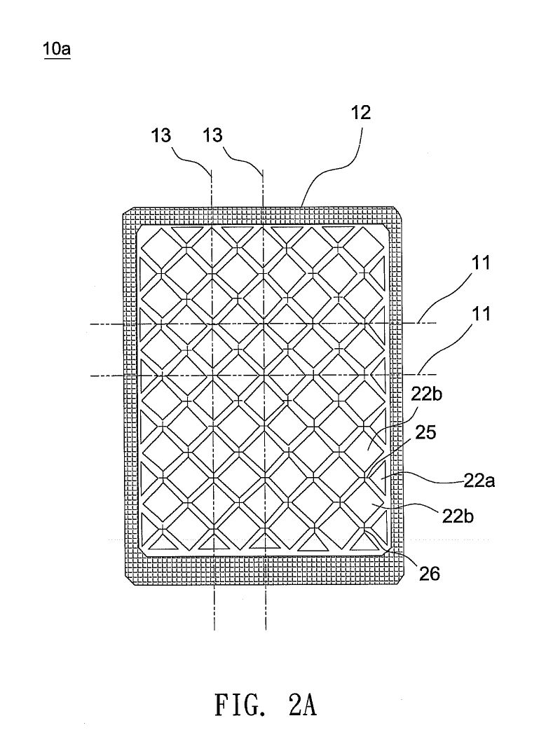

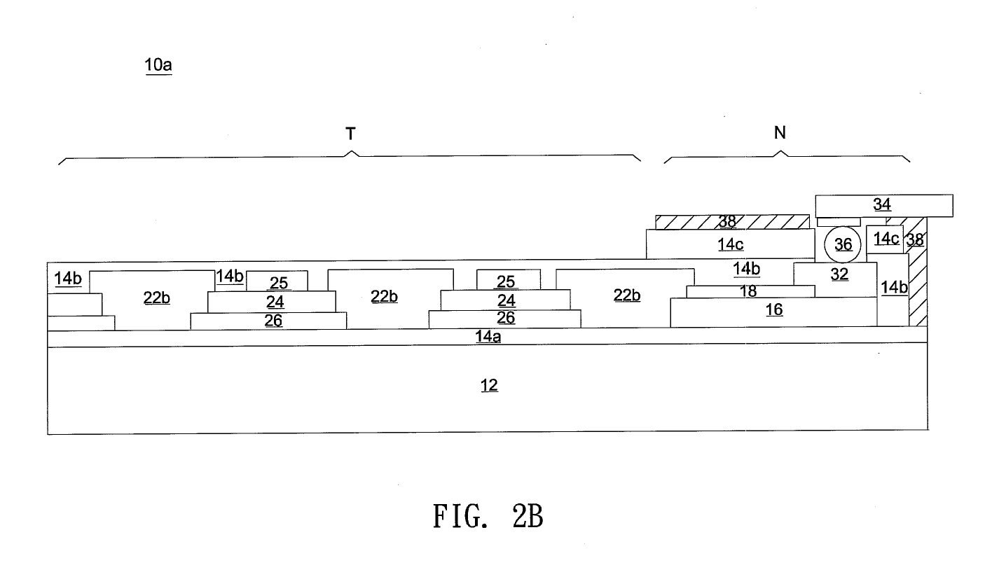

FIG. 2A shows a plan view of a touch-sensitive device according to an embodiment of the invention, and FIG. 2B shows an enlarged cross-section of FIG. 2A. As shown in FIG. 2A and FIG. 2B, a touch-sensitive device 10a includes a transparent substrate 12 and a laminated structure formed on the transparent substrate 12. The touch-sensitive device 10a is divided into a touch-sensitive region T and a non-touch-sensitive region N. In this embodiment, the non-touch-sensitive region N is located on the periphery of the touch-sensitive device 10a and surrounds the touch-sensitive region T. A touch-sensing structure is substantially formed in the touch-sensitive region T of the touch-sensitive device 10a to detect touch operations. The laminated structure in the non-touch-sensitive region N includes a first buffer layer 14a, a decorative layer 16 and a metal trace layer 18. The first buffer layer 14a may be formed on and cover the transparent substrate 12, and the decorative layer 16 and the metal trace layer 18 are disposed on the transparent substrate 12 in succession. The material of the transparent substrate 12 includes but not limited to glass or plastic. Further, the transparent substrate 12 may function as a cover lens. The metal trace layer 18 includes a plurality of metal traces, and a touch-sensing structure in the touch-sensitive region T is connected to an external circuit through the metal traces. The decorative layer 16 is formed on the periphery of the transparent substrate 12 to shield metal traces. The material of the decorative layer 16 includes diamond-like carbon, ceramic, colored ink, resin, photo resist or the combination thereof. The touch-sensing structure in the touch-sensitive region T may be a single-layer electrode structure or a multi-layer electrode structure. In the present embodiment, the touch-sensing structure may include a plurality of first sensing series 11 and a plurality of second sensing series 13 spaced apart from the first sensing series 11. For example, as shown in FIG. 2B, the touch-sensing structure has an underground-island electrode structure, where each first sensing series 11 includes multiple first transparent electrodes 22a connected with each other by multiple first connecting lines 25, each second sensing series 13 includes multiple second transparent electrodes 22b connected with each other by multiple second connecting lines 26, and a dielectric layer 24 is disposed between the corresponding first connecting line 25 and second connecting line 26. The second connecting lines 26 are formed in a fabrication process different to the fabrication processes of the first connecting lines 25, the first transparent electrodes 22a and the second transparent electrodes 22b. Besides, the second connecting lines 26 may be disposed between the dielectric layer 24 and first buffer layer 14a. Note the touch-sensing structure is not limited to an underground-island electrode structure. In an alternate embodiment, the connecting lines are connected with each other in the upper portion of the touch-sensing structure to form a bridge-island electrode structure. Further, the touch-sensing structure may be disposed on two opposite sides of the transparent substrate 12, and the transparent electrodes may have a regular shape such as a diamond, a triangle or a line segment or may have an irregular shape.

Further, the first buffer layer 14a is an auxiliary layer used to enhance the adherence between the transparent substrate 12 and the first transparent electrodes 22a, the second transparent electrodes 22b and the second connecting lines 26. Certainly, the first buffer layer 14a may be omitted in other embodiments. In this embodiment, the first buffer layer 14a may be made from an inorganic material such as silicon dioxide (SiO₂).

In this embodiment, a first insulation layer 14b covers both a touch-sensing structure in the touch-sensitive region T and a laminated structure in the non-touch-sensitive region N to protect the entire touch-sensitive device 10a. The first insulation layer 14b may be made from an inorganic material such as silicide. In this embodiment, a second insulation layer 14c is formed on the first insulation layer 14b and distributed only in the non-touch-sensitive region N, and the thickness of the second insulation layer 14c is 10-50 times greater than the thickness of the first insulation layer 14b. The second insulation layer 14c may be made from an inorganic material or an organic material. Further, an ink layer 38 is distributed on the periphery of the laminated structure in the non-touch-sensitive region N. The ink layer 38 at least overlaps a gap region between an outer edge of the decorative layer 16 and a side edge of the transparent substrate 12 to avoid peripheral light leakage. Besides, in this embodiment, the ink layer 38 is disposed on the periphery of the touch-sensitive device 10a to surround the decorative layer 16 on the metal trace layer 18 to provide periphery protection of the wiring structure on the cover lens and to avoid side scrapes on the decorative layer 16 to improve production reliability. For example, the ink layer 38 may have an L-shaped cross-section as shown in FIG. 2B. In this embodiment, a transparent conductive layer 32 is formed on the decorative layer 16 and electrically connected to the metal traces in the metal trace layer 18. The material of the transparent conductive layer 32 includes but not limited to an ITO transparent conductive film. The first insulation layer 14b covers the metal trace layer 18, and an opening is formed on the first insulation layer 14b at a position overlapping a bonding area of the transparent conductive layer 32. Besides, another opening is formed on the second insulation layer 14c above the first insulation layer 14b to expose a part of the transparent conductive layer 32. The exposed part of the transparent conductive layer 32 is electrically connected to a transmission device (such as a flexible printed circuit board 34) or an electronic device (such as an IC chip) through an anisotropic conductive film (ACF) 36.

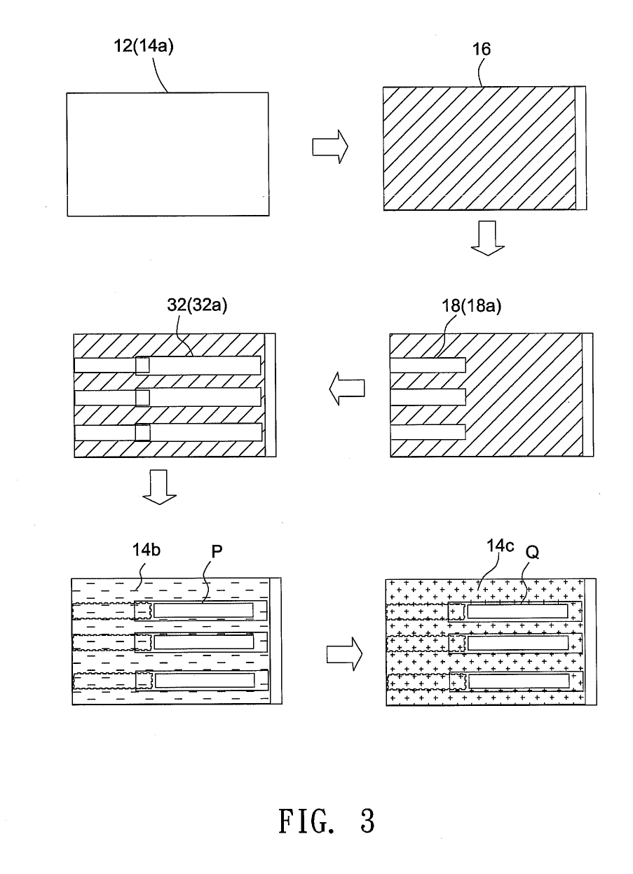

FIG. 3 shows a flow diagram illustrating a fabrication method of the non-touch-sensitive region N in the touch-sensitive device shown in FIG. 2. Referring to FIG. 3, the first buffer layer 14a, the decorative layer 16, and the metal trace layer 18 having multiple metal traces 18a are formed in succession on the transparent substrate 12, and then a transparent conductive film is provided on the transparent substrate 12 and patterned to form the transparent conductive layer 32 having multiple conductive pads 32a on the decorative layer 16. Thereafter, a first insulation layer 14b is formed on the metal trace layer 18 and the transparent conductive layer 32, and an opening is formed on the first insulation layer 14b at a position overlapping the bonding area to expose a part of the transparent conductive layer 32 to provide an electrical connection between an external circuit and the transparent conductive layer 32. Further, a second insulation layer 14c may be selectively formed on the first insulation layer 14b. In case the second insulation layer 14c is formed on the first insulation layer 14b, another opening Q is formed on the second insulation layer 14c at a position overlapping the opening P to expose the part of the transparent conductive layer 32.

According to the above embodiments, the metal trace layer 18 are surrounded by the first insulation layer 14b and the transparent conductive layer 32 to prevent the metal traces in the metal trace layer 18 from absorbing moisture or suffering scrapes to improve production yields and reliability. Besides, the transparent conductive layer 32, the first transparent electrodes 22a, the second transparent electrodes 22b and the first connecting lines 25 are formed in the same fabrication process to prevent additional fabrication processes and costs.

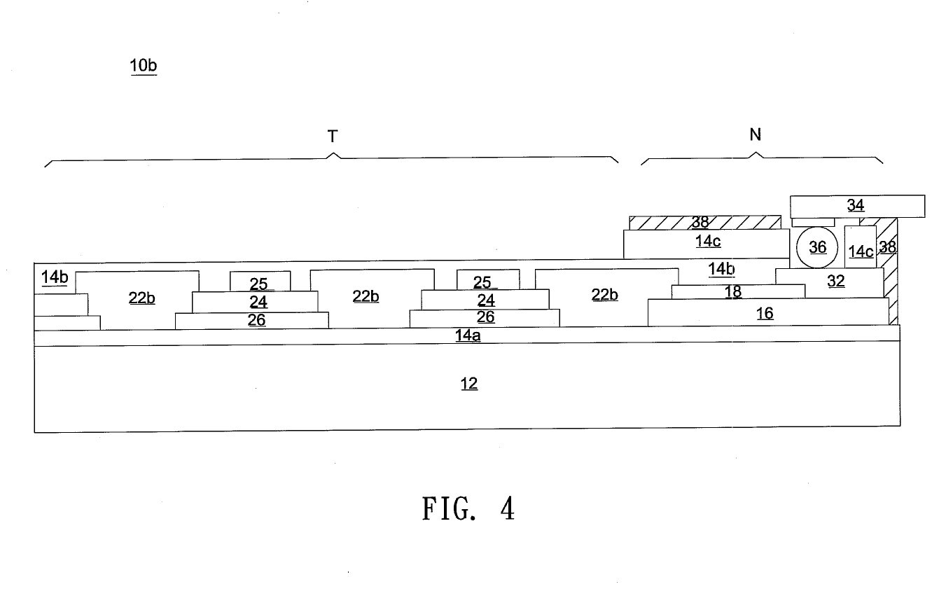

FIG. 4 shows a schematic diagram of a touch-sensitive device 10b according to another embodiment of the invention. Referring to FIG. 4, a touch-sensing structure in the touch-sensitive region T is similar to the touch-sensing structure shown in FIG. 2B, but a laminated structure in the non-touch-sensitive region N is different to the laminated structure shown in FIG. 2B. In this embodiment, the first insulation layer 14b is not extended into the bonding area of the transparent conductive layer 32, so only the second insulation layer 14c is provided with an opening at a position overlapping the bonding area of the transparent conductive layer 32 to expose a part of the transparent conductive layer 32. The ink layer 38 may surround the decorative layer 16 on the second insulation layer 14c.

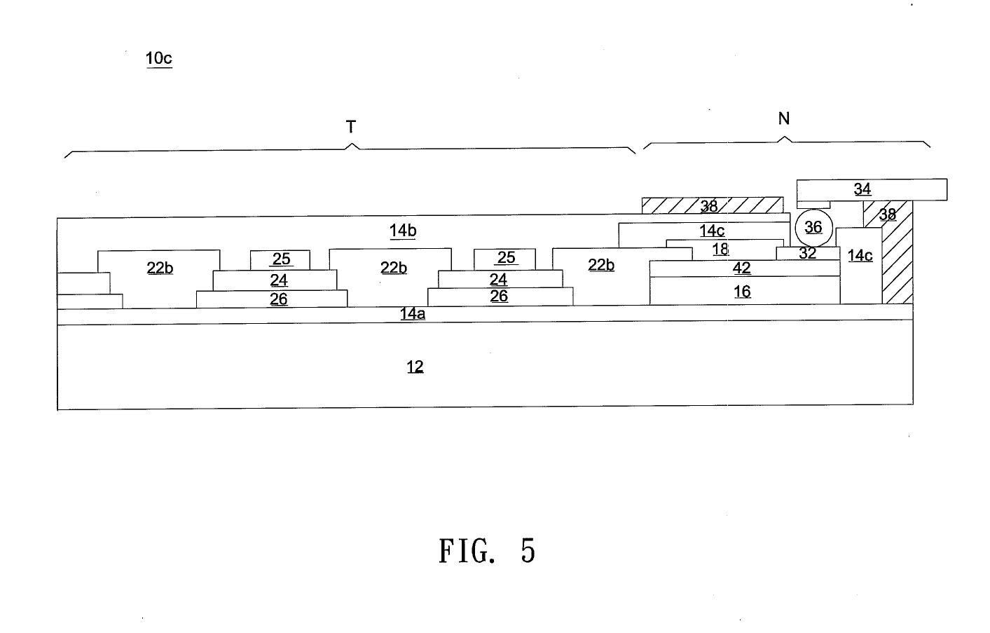

FIG. 5 shows a schematic diagram of a touch-sensitive device 10c according to another embodiment of the invention. Referring to FIG. 5, a second buffer layer 42 is formed between the decorative layer 16 and the metal trace layer 18 and the transparent conductive layer 32. The second buffer layer 42 made from an inorganic material such as silicon dioxide (SiO2) can enhance the connection strength between the metal trace layer 18 and the decorative layer 16. Besides, in this embodiment, the second insulation layer 14c extends in two directions respectively parallel to and perpendicular to the transparent substrate 12 to surround one side of the decorative layer 16. The thicker second insulation layer 14c is formed on the metal trace layer 18 and the transparent conductive layer 32 first, and then the thinner first insulation layer 14b is formed on the second insulation layer 14c. Note the transparent conductive layer 32 may be formed on the metal trace layer 18 (FIG. 4), or the metal trace layer 18 may be formed on the transparent conductive layer 32 (FIG. 5).

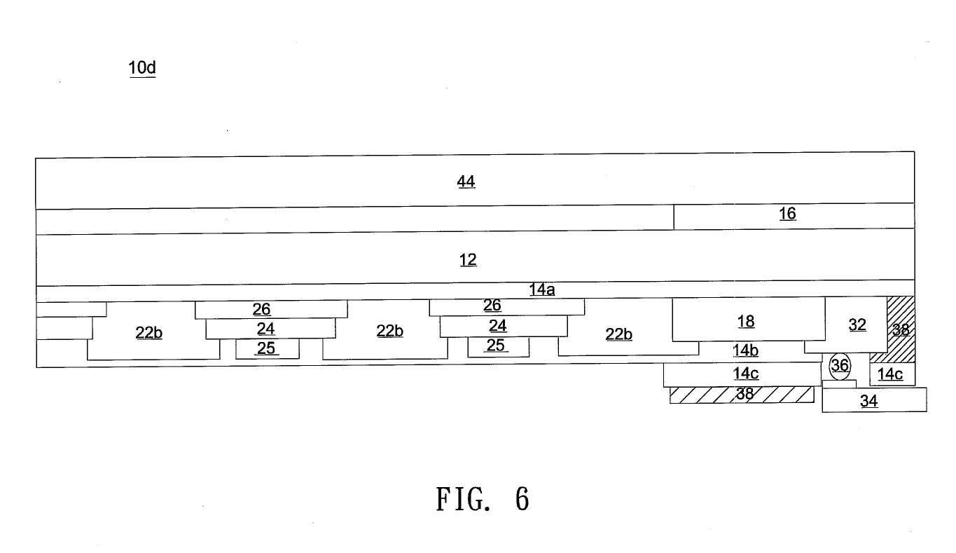

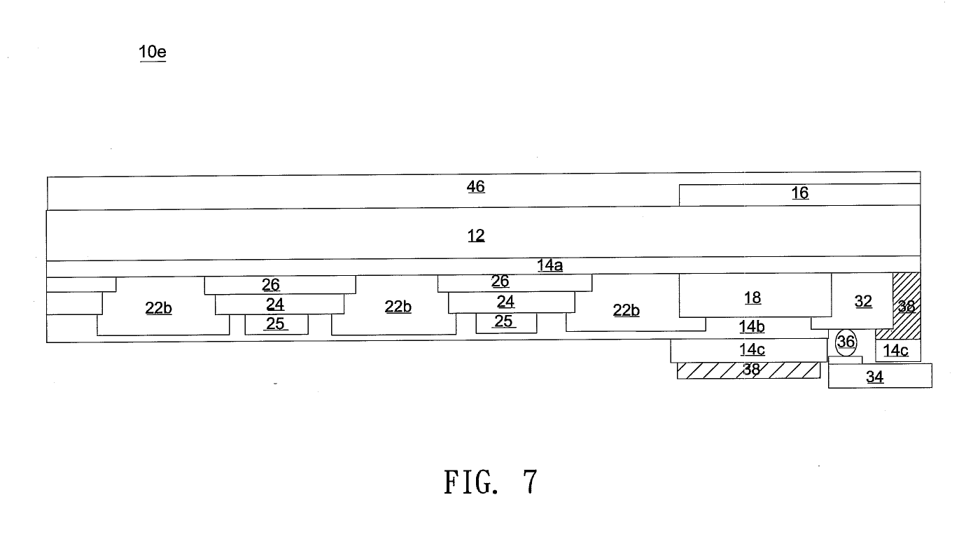

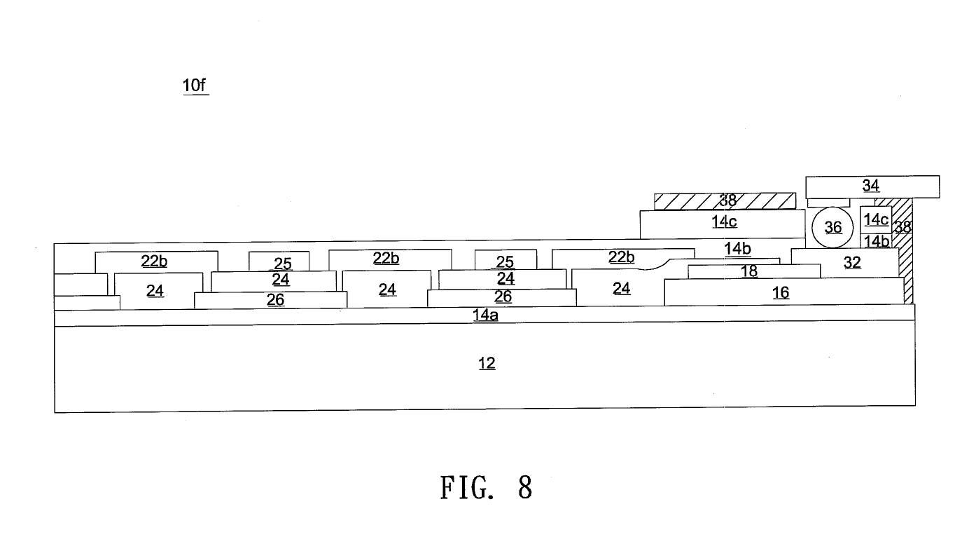

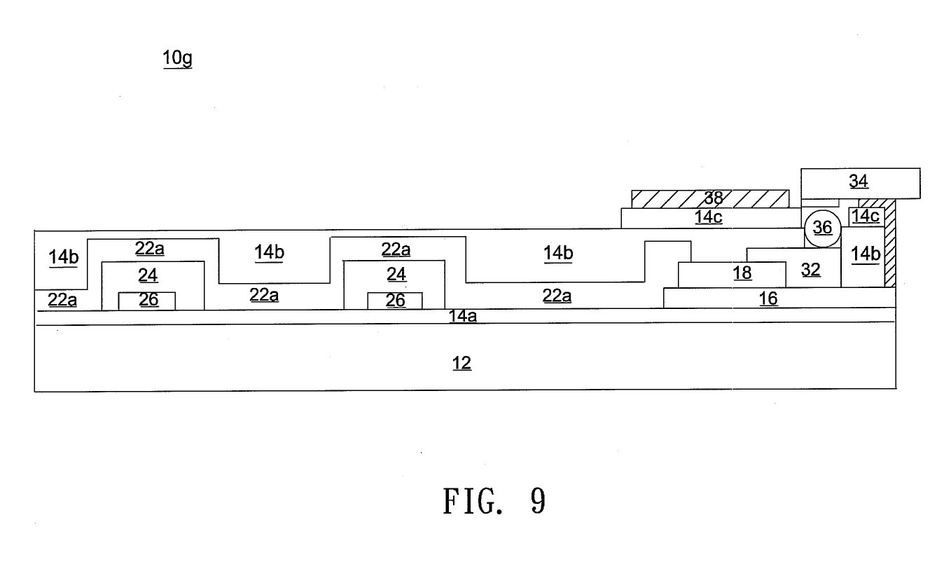

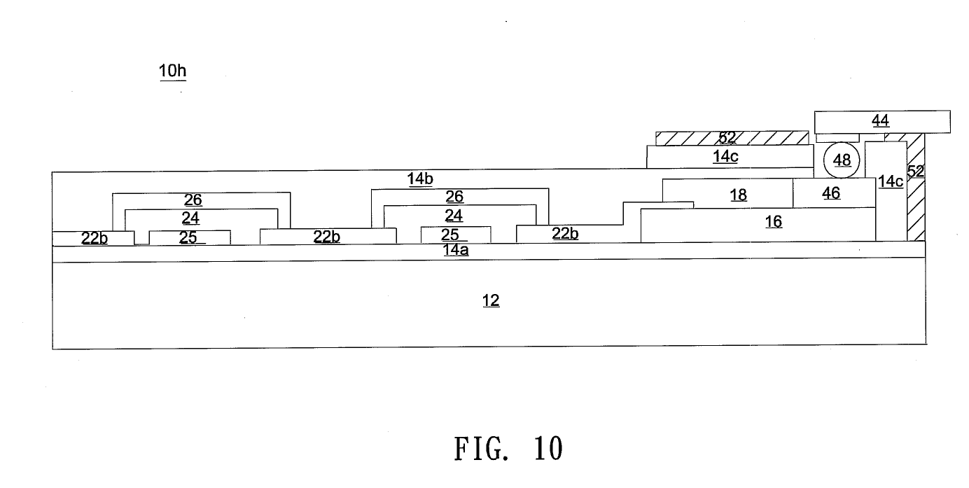

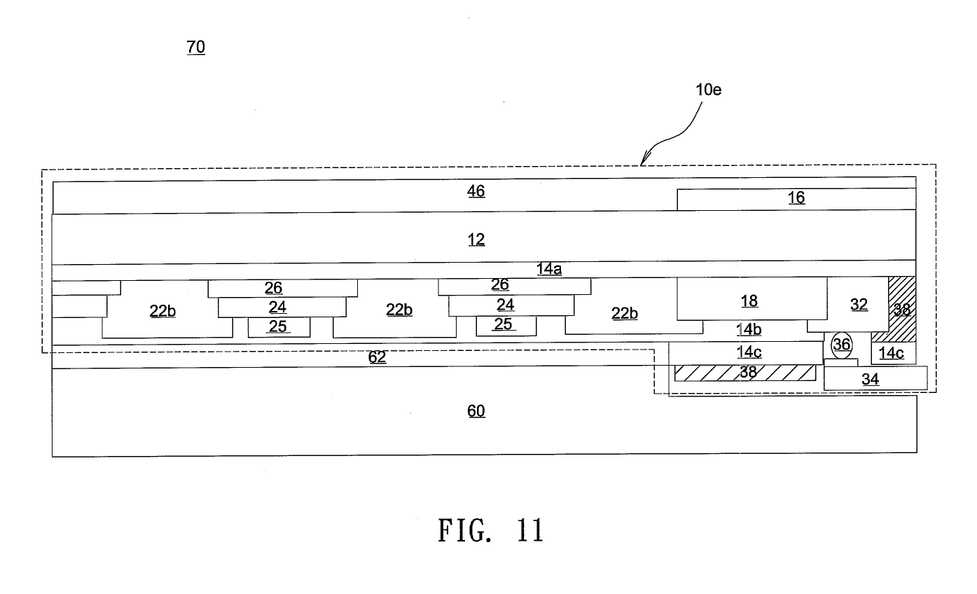

Referring to FIG. 6, a touch-sensitive device 10d includes a cover glass 44. The cover glass 44 is formed on one side of the transparent substrate 12 opposite the metal trace layer 18 and has a decorative layer 16. The decorative layer 16 is formed on one side of the cover glass 44 facing the transparent substrate 12 to allow the cover glass 44 to shield the metal traces and protect the entire touch-sensitive device 10d. Further, the metal trace layer 18 and the transparent conductive layer 32 may be formed on the first buffer layer 14a. As shown in FIG. 7, the cover glass 44 in a touch-sensitive device 10e may be omitted, and the decorative layer 16 is directly formed on one side of the transparent substrate 12 opposite the metal trace layer 18. Further, a passivation layer 46 may be formed on the decorative layer 16 to serve protection purposes. The material of the passivation layer 46 includes but not limited to polyethylene terephthalate (PET). FIG. 8 shows a schematic diagram of a touch-sensitive device 10f according to another embodiment of the invention. FIG. 9 shows a schematic diagram of a touch-sensitive device 10g according to another embodiment of the invention. FIG. 8 and FIG. 9 illustrate different designs of a touch-sensing structure. Further, as shown in FIG. 10, the second connecting lines 26 in the touch-sensitive device 10h may be disposed between the first insulation layer 14b and the dielectric layer 24. Note the configuration of a touch-sensing structure in the touch-sensitive region is not restricted, as long as the effect of detecting touch operations is achieved. For example, the touch-sensing structure may be an underground electrode structure, a bridge electrode structure or other electrode structure. Further, as shown in FIG. 11, the touch-sensitive device (such as the touch-sensitive device 10e) in the above embodiments may be connected to a display device 60 by, for example, an optical adhesive 62 to form a touch-sensitive display device 70. The type of the display device 60 includes but not limited to a liquid crystal display, an organic light-emitting diode display, an electro-wetting display, a bi-stable display, and an electrophoretic display.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims. Each of the terms “first” and “second” is only a nomenclature used to modify its corresponding elements. These terms are not used to set up the upper limit or lower limit of the number of bumps.

What is claimed is:

1. A touch-sensitive device having a touch-sensitive region and a non-touch-sensitive region and comprising:
a transparent substrate;
a touch-sensing structure disposed on the transparent substrate, located in the touch-sensitive region, and comprising a plurality of first sensing series and a plurality of second sensing series;
a metal trace layer disposed on the non-touch-sensitive region;
a transparent conductive layer disposed on the transparent substrate, located in the non-touch-sensitive region, and electrically connected to the metal trace layer; and
a first insulation layer disposed on the transparent substrate and covering the touch-sensing structure, the metal trace layer and the transparent conductive layer, wherein at least one opening is formed on the first insulation layer to expose a part of the transparent conductive layer.

2. The touch-sensitive device as claimed in claim 1, further comprising:
a decorative layer disposed on the non-touch-sensitive region.

3. The touch-sensitive device as claimed in claim 2, further comprising:
a first buffer layer formed on the transparent substrate and covering the transparent substrate, wherein the decorative layer is formed on the first buffer layer and the metal trace layer and the transparent conductive layer are formed on the decorative layer.

4. The touch-sensitive device as claimed in claim 3, further comprising:
a second buffer layer formed between the metal trace layer and the decorative layer.

5. The touch-sensitive device as claimed in claim 4, wherein the first buffer layer and the second buffer layer are made from an inorganic material.

6. The touch-sensitive device as claimed in claim 2, further comprising:
a second insulation layer disposed on the transparent substrate and distributed only in the non-touch-sensitive region.

7. The touch-sensitive device as claimed in claim 6, wherein the second insulation layer is formed on the first insulation layer, at least one opening is formed on the second insulation layer to expose the part of the transparent conductive layer, and the opening formed on the second insulation layer substantially overlaps the opening formed on the first insulation layer.

8. The touch-sensitive device as claimed in claim 6, wherein the second insulation layer is formed between the first insulation layer and the metal trace layer.

9. The touch-sensitive device as claimed in claim 6, wherein the second insulation layer surrounds one side of the decorative layer.

10. The touch-sensitive device as claimed in claim 6, wherein the thickness of the second insulation layer is 10-50 times greater than the thickness of the first insulation layer.

11. The touch-sensitive device as claimed in claim 6, wherein the second insulation layer is made from an inorganic material or an organic material.

12. The touch-sensitive device as claimed in claim 1, wherein each of the first sensing series comprises a plurality of first transparent electrodes connected with each other by a plurality of first connecting lines, each of the second sensing series comprises a plurality of second transparent electrodes connected with each other by a plurality of second connecting lines, the second connecting lines are formed in a fabrication process different to the fabrication processes of the first connecting lines, the first transparent electrodes and the second transparent electrodes, and a dielectric layer is disposed between the corresponding first connecting line and second connecting line.

13. The touch-sensitive device as claimed in claim 12, further comprising:
a first buffer layer formed on the transparent substrate and covering the transparent substrate, wherein the second connecting lines are disposed between the first buffer layer and the dielectric layer or between the dielectric layer and the first insulation layer.

14. The touch-sensitive device as claimed in claim 2, wherein the decorative layer is formed on one side of the transparent substrate opposite the metal trace layer.

15. The touch-sensitive device as claimed in claim 14, further comprising:
a passivation layer formed on one side of the transparent substrate opposite the metal trace layer and covering the decorative layer.

16. The touch-sensitive device as claimed in claim 2, further comprising:
a cover glass disposed on one side of the transparent substrate opposite the metal trace layer, wherein the decorative layer is formed on one side of the cover glass facing the transparent substrate.

17. The touch-sensitive device as claimed in claim 2, wherein the material of the decorative layer comprises at least one of diamond-like carbon, ceramic, colored ink, resin and photo resist.

18. The touch-sensitive device as claimed in claim 1, wherein the transparent substrate is a glass substrate or a plastic substrate.

19. The touch-sensitive device as claimed in claim 1, wherein the first insulation layer is made from an inorganic material.

20. The touch-sensitive device as claimed in claim 1, further comprising:
an ink layer disposed on the periphery of the touch-sensitive device.

21. The touch-sensitive device as claimed in claim 20, wherein the ink layer has an L-shaped cross-section.

22. A touch-sensitive display device, comprising:
a touch-sensitive device having a touch-sensitive region and a non-touch-sensitive region and comprising:
a transparent substrate;
a touch-sensing structure disposed on the transparent substrate, located in the touch-sensitive region, and comprising a plurality of first sensing series and a plurality of second sensing series;
a metal trace layer disposed on the non-touch-sensitive region;
a transparent conductive layer disposed on the transparent substrate, located in the non-touch-sensitive region, and electrically connected to the metal trace layer; and
a first insulation layer disposed on the transparent substrate and covering the touch-sensing structure, the metal trace layer and the transparent conductive layer, wherein at least one opening is formed on the first insulation layer to expose a part of the transparent conductive layer; and
a display device in combination with the touch-sensitive device.

23. The touch-sensitive display device as claimed in claim 22, wherein the display device is a liquid crystal display, an organic light-emitting diode display, an electro-wetting display, a bi-stable display, or an electrophoretic display.

24. A fabrication method of a touch-sensitive device, comprising the steps of:
providing a transparent substrate;
forming a decorative layer on the transparent substrate;
forming a metal trace layer on the decorative layer;
forming a transparent conductive layer on the transparent substrate, wherein the transparent conductive layer is patterned to form a plurality of first sensing series and a plurality of second sensing series in a touch-sensitive region of the touch-sensitive device and to form a transparent conductive layer in a non-touch-sensitive region of the touch-sensitive device;
forming an insulation layer on the transparent conductive layer; and
forming at least one opening on the insulation layer to expose a part of the transparent conductive layer to enable the transparent conductive layer to electrically connect with an external circuit.
